(19) United States
(12) Patent Application Publication
(10) Pub. No.: US 2026/0142563 A1
(43) Pub. Date: May 21, 2026

(54) SEMICONDUCTOR DEVICE AND POWER CONVERTER

(71) Applicant: DENSO CORPORATION, Kariya-city (JP)

(72) Inventor: Yuya HASHIMOTO, Kariya-city (JP)

(73) Assignee: DENSO CORPORATION, Kariya-city (JP)

(21) Appl. No.: 19/447,112

(22) Filed: Jan. 13, 2026

Related U.S. Application Data
(63) Continuation of application No. PCT/JP2024/025493, filed on Jul. 16, 2024.

(30) Foreign Application Priority Data
Aug. 8, 2023 (JP) 2023-129544

(51) Int. Cl. H02M 1/34; H02M 7/00; H02P 27/00; H10W 70/65; H10W 90/10

(52) U.S. Cl. CPC H02M 1/348; H02M 7/003; H10W 70/658; H10W 90/10; H02P 27/00

(57) ABSTRACT

A semiconductor device includes a first semiconductor element forming an upper arm and a second semiconductor element forming a lower arm. The first semiconductor element and the second semiconductor element are arranged in an element arrangement direction to form a semiconductor element group. The semiconductor device includes a snubber circuit component that forms a snubber circuit connected in parallel to the upper arm and the lower arm. The snubber circuit component is located adjacent to the semiconductor element group in the element arrangement direction.

### CROSS REFERENCE TO RELATED APPLICATIONS

The present application is a continuation application of International Patent Application No. PCT/JP2024/025493 filed on Jul. 16, 2024, which designated the U.S. and claims the benefit of priority from Japanese Patent Application No. 2023-129544, filed on Aug. 8, 2023. The entire disclosures of all of the above applications are incorporated herein by reference.

### TECHNICAL FIELD

The disclosure in this specification relates to a semiconductor device and a power converter.

### BACKGROUND

A semiconductor device may have a snubber circuit that is disposed adjacent to both a semiconductor element forming an upper arm and another semiconductor element forming a lower arm.

### SUMMARY

According to an aspect of the present disclosure, a semiconductor device includes a first semiconductor element, a second semiconductor element, and a snubber circuit component. The first semiconductor element forms an upper arm. The second semiconductor element forms a lower arm. The snubber circuit component may be included in a snubber circuit that is connected in parallel to the upper arm and the lower arm. The first semiconductor element and the second semiconductor element are arranged in an element arrangement direction to form a semiconductor element group. The snubber circuit component may be located adjacent to the semiconductor element group in the element arrangement direction.

### BRIEF DESCRIPTION OF DRAWINGS

FIG. 1 is a circuit diagram that illustrates a power converter according to a first embodiment.

FIG. 2 is a plan view for explaining the configuration of a semiconductor device.

FIG. 3 is a cross-sectional view that illustrates a part of the configuration of the semiconductor device.

FIG. 4 is a plan view that illustrates the positional relationship between the semiconductor elements and snubber circuits of the upper and lower arms.

FIG. 5 is a plan view that illustrates the positional relationship between the semiconductor elements and snubber circuits of the upper and lower arms.

FIG. 6 is a plan view that illustrates the positional relationship between the semiconductor elements and snubber circuits of the upper and lower arms.

### DETAILED DESCRIPTION

In a semiconductor device in the related filed, a snubber circuit is arranged alongside both the upper arm and lower arm semiconductor elements in a direction perpendicular to the direction in which the semiconductor elements of the upper and lower arms are arranged.

However, in the semiconductor device described above, a snubber circuit face both semiconductor elements, and therefore are susceptible to the effects of heat dissipation from both semiconductor elements.

According to an aspect of the present disclosure, a semiconductor device includes a first semiconductor element, a second semiconductor element, and a snubber circuit component. The first semiconductor element forms an upper arm. The second semiconductor element forms a lower arm. The snubber circuit component forms a snubber circuit that is connected in parallel to the upper arm and the lower arm. The first semiconductor element and the second semiconductor element are arranged in an element arrangement direction to form a semiconductor element group. The snubber circuit component is located adjacent to the semiconductor element group in the element arrangement direction. According to another aspect of the present disclosure, a power converter includes the above-mentioned semiconductor device and a smoothing capacitor.

According to this semiconductor device, the snubber circuit component is provided adjacent to one of the first and second semiconductor elements, but not adjacent to the other. The first and second semiconductor elements are arranged in alignment. As a result, it is possible to suppress the thermal influence on the snubber circuit from the other semiconductor element among the semiconductor elements forming the upper and lower arms. This semiconductor device can thereby suppress the thermal influence of the semiconductor element on the snubber circuit. Furthermore, by employing a configuration including this semiconductor device, it is possible to provide a power converter capable of suppressing the thermal influence of the semiconductor element on the snubber circuit.

Below, several embodiments for carrying out the present disclosure will be described with reference to the drawings. In each embodiment, parts corresponding to the matters described in its preceding embodiment(s) will be denoted by the same reference signs as in the preceding embodiment(s), and duplication of description will be omitted as appropriate. In each embodiment, in a case where only a part of the configuration is described, the other parts of the configuration can be implemented by application of the other embodiments described ahead thereof. It may be possible not only to combine parts the combination of which is explicitly described in an embodiment, but also to combine parts of respective embodiments the combination of which is not explicitly described if any obstacle does not especially occur in combining the parts of the respective embodiments.

### First Embodiment

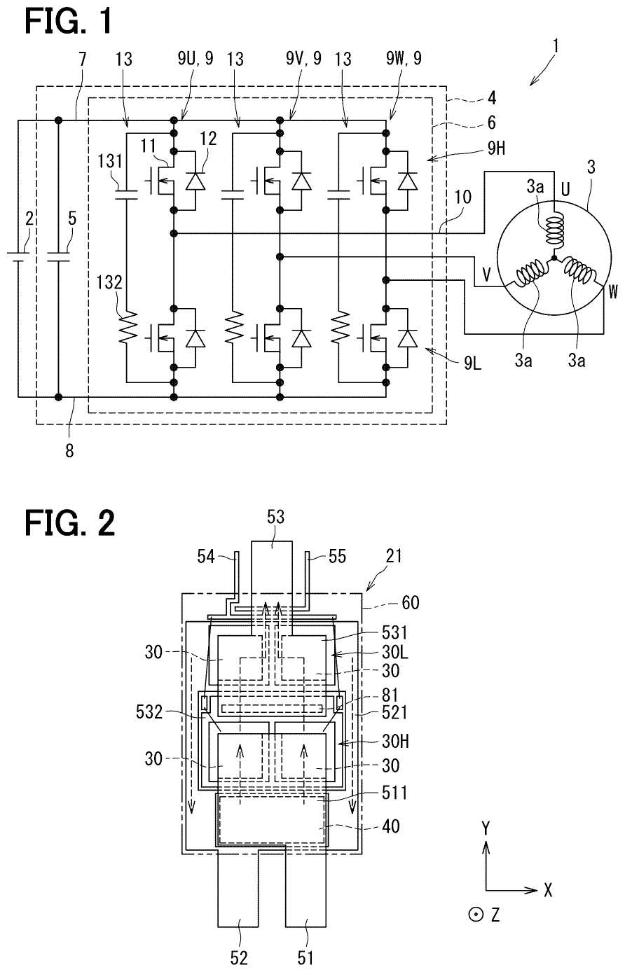

A first embodiment showing an example of a power converter will be described with reference to FIGS. 1 to 3. Examples of applications of the power converter are as follows. The power converter can be applied to onboard power converters installed in vehicles such as electric vehicles, hybrid vehicles, and plug-in hybrid vehicles. The power converter can also be installed in aircraft such as electric vertical take-off and landing vehicles and drones, as well as in ships, construction machinery, and agricultural machinery. The following describes an example in which the power converter is applied to a vehicle.

As shown in FIG. 1, a drive system 1 of the vehicle includes a DC power supply 2, a motor generator 3, and a power converter 4. The DC power supply 2 is a DC voltage source includes a rechargeable secondary battery. The secondary battery may be, for example, a lithium-ion battery or a nickel-metal hydride battery. The motor generator 3 is, for example, a rotary electric machine of a three-phase AC type. The motor generator 3 functions as a driving power source for the vehicle, that is, as an electric motor. The motor generator 3 functions as a generator during regenerative operation. The power converter 4 performs power conversion between the DC power supply 2 and the motor generator 3.

The power converter 4 has a power conversion circuit. As shown in FIG. 1, the power converter 4 has a smoothing capacitor 5 and an inverter 6, which serves as the power conversion circuit. The smoothing capacitor 5 primarily functions to smoothen the DC voltage supplied from the DC power supply 2. The smoothing capacitor 5 is connected to the P line 7, which is the high-potential power supply line, and the N line 8, which is the low-potential power supply line.

The smoothing capacitor 5 is connected in parallel to the DC power supply 2. The P line 7 is connected to the positive terminal of the DC power supply 2. The N line 8 is connected to the negative terminal of the DC power supply 2. The positive terminal of the smoothing capacitor 5 is connected to the P line 7 between the DC power supply 2 and the inverter 6. The negative terminal of the smoothing capacitor 5 is connected to the N line 8 between the DC power supply 2 and the inverter 6. The P line 7 includes P busbars, each of which connects electrical components to other electrical components. The N line 8 includes N busbars, each of which connects electrical components to other electrical components.

The inverter 6 is a DC-AC conversion circuit. The inverter 6 converts the DC voltage into a three-phase AC voltage and outputs the converted voltage to the motor generator 3 in accordance with switching control performed by a control circuit provided on the control circuit board. By this operation, the motor generator 3 is driven to generate a predetermined torque. During regenerative braking of the vehicle, the inverter 6 converts the three-phase AC voltage generated by the motor generator 3, which receives rotational force from the wheels, into DC voltage in accordance with switching control by the control circuit. The converted DC power is output to the P line 7. In this manner, the inverter 6 performs bidirectional power conversion between the DC power supply 2 and the motor generator 3.

The control circuit for the switching element generates a drive command for operating the MOSFET 11 and outputs generated command to the drive circuit. The control circuit generates drive commands based on, for example, torque requests received from a higher-level ECU and signals detected by various sensors. ECU is an abbreviation for Electronic Control Unit. Various sensors include, for example, a current sensor, a rotational angle sensor, and a voltage sensor. The current sensor detects the phase current flowing through the winding 3a of each phase. The rotational angle sensor detects the rotational angle of the rotor of the motor generator 3. The voltage sensor detects the voltage across both terminals of the smoothing capacitor 5. The control circuit outputs, for example, a PWM signal as a drive command. The control circuit is configured to include, for example, a processor and memory. PWM is an abbreviation for Pulse Width Modulation.

The inverter 6 has upper-lower arm circuits 9 for the three phases, respectively. The upper-lower arm circuits 9 may also be referred to as legs. The upper-lower arm circuit 9 include an upper arm 9H and a lower arm 9L. The upper arm 9H and the lower arm 9L are connected in series between the P line 7 and the N line 8, with the upper arm 9H on the P line 7 side and the lower arm 9L on the N line 8 side.

The connection node between the upper arm 9H and the lower arm 9L is connected to the corresponding phase winding 3a of the motor generator 3 via an output line 10. Among the upper-lower arm circuits 9, an upper-lower arm circuit 9U for the U phase is connected to the U-phase winding 3a via the corresponding output line 10. The V-phase upper-lower arm circuit 9V is connected to the V-phase winding 3a via the corresponding output line 10. An upper-lower arm circuit 9W for the W phase is connected to the W-phase winding 3a via the corresponding output line 10. At least a portion of the output line 10 is formed of a conductive member, such as a busbar.

The inverter 6 includes six arms, each provided with a switching element. The number of switching elements included in each arm is not particularly limited and may be one or more. In cases where switching elements are provided, the switching elements connected in parallel are driven ON and OFF simultaneously by a common gate drive signal.

In this specification, an n-channel MOSFET 11 is employed as the switching element included in each arm. “MOSFET” is an abbreviation for Metal Oxide Semiconductor Field Effect Transistor. In the upper arm 9H, the drain of the MOSFET 11 is connected to the P line 7. In the lower arm 9L, the source of the MOSFET 11 is connected to the N line 8. The source of the MOSFET 11 in the upper arm 9H and the drain of the MOSFET 11 in the lower arm 9L are interconnected.

A freewheeling diode 12 is connected in reverse parallel to each of the MOSFETs 11. The diode 12 may be the parasitic diode of the MOSFET 11, or may be provided separately from the parasitic diode. The anode of the diode 12 is connected to the source of the corresponding MOSFET 11, and the cathode of the diode 12 is connected to the drain.

The switching element is not limited to the MOSFET 11; an IGBT may also be used as the switching element. “IGBT” is an abbreviation for Insulated Gate Bipolar Transistor. In the case where an IGBT is employed, a freewheeling diode is also connected in reverse parallel to the IGBT.

The inverter 6 includes snubber circuits 13, in addition to the upper-lower arm circuits 9 described above. The snubber circuit 13 absorbs a transient high voltage that occurs during switching, that is, a switching surge. This allows for high-speed switching. The snubber circuits 13 may be provided individually for the upper-lower arm circuits 9, and connected in parallel to the corresponding upper-lower arm circuit 9.

The snubber circuit 13 includes at least a capacitor 131. The snubber circuit 13 may be, for example, a C snubber circuit having a capacitor 131, or an RC snubber circuit having both a capacitor 131 and a resistor 132, as shown in FIG. 1. An RCD snubber circuit having a capacitor 131, a resistor 132, and a diode may also be used.

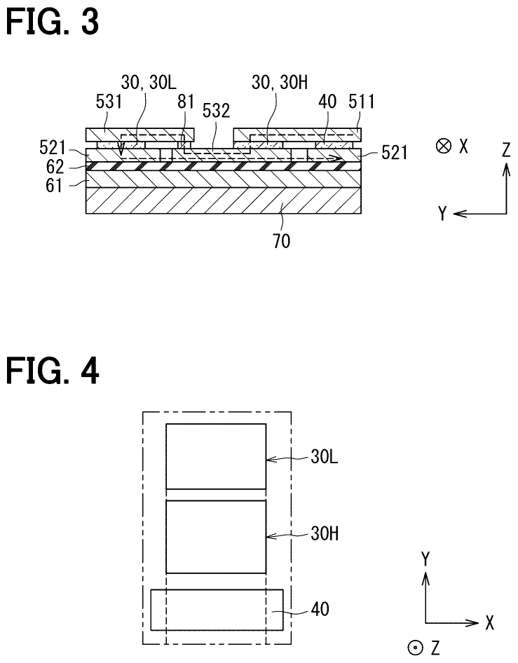

FIG. 2 is a plan view illustrating the configuration of an example of a semiconductor device. FIG. 3 is a cross-sectional view showing a part of the semiconductor device. In the following description, the thickness direction of the substrate is defined as the Z direction, and a direction perpendicular to the Z direction is defined as the Y direction. A direction perpendicular to both the Z direction and the Y direction is defined as the X direction. Unless otherwise specified, the shape viewed in plan along the Z direction, that is, the shape along the XY plane defined by the X and Y directions, is referred to as the planar shape. Additionally, a plan view in the Z direction may simply be referred to as a plan view.

As shown in FIG. 2, the semiconductor device 21 includes an upper-lower arm circuit 9, a snubber circuit component 40, and a housing 60. As shown in FIG. 3, the semiconductor device 21 may further be configured to include a cooler 70. The semiconductor device 21, together with a capacitor device that provides a smoothing capacitor 5, an input terminal block, and an output terminal block, is included in the power converter 4. The semiconductor device 21 may also be configured to be housed, together with other elements such as the capacitor device, in a case that forms the outer shell of the power converter 4.

The semiconductor device 21 includes a first semiconductor element 30H that is included in the upper arm 9H and a second semiconductor element 30L that is included in the lower arm 9L. The first semiconductor element 30H and the second semiconductor element 30L form a group of semiconductor elements arranged side by side in the element arrangement direction. The element arrangement direction corresponds to the Y direction in each of the figures. The semiconductor device 21 has the snubber circuit component 40, which is arranged adjacent to the semiconductor group in the element arrangement direction. The snubber circuit component 40 includes the snubber circuit 13 that is connected in parallel to the upper arm 9H and the lower arm 9L. The snubber circuit component 40 is formed, for example, by a thin-film element.

The first semiconductor element 30H has a flat external shape and includes multiple semiconductor elements 30 within its exterior. The second semiconductor element 30L has a flat external shape and includes the multiple semiconductor elements 30 within its exterior. Here, “multiple” refers to two or more. The number of the semiconductor elements 30 included in each of the first semiconductor element 30H and the second semiconductor element 30L is not particularly limited. There may be only one in each, or there may be multiple elements in each. The multiple semiconductor elements 30 are connected in parallel to provide the MOSFET 11 for one phase arm. The multiple semiconductor elements 30 are arranged in the X direction.

The flat-shaped outer shell is, for example, in the form of a thin plate or a thin film. Each semiconductor element 30 is provided in an orientation such that its thickness direction, which is the direction of its minimum dimension length, is perpendicular to the direction in which the elements are arranged. The thickness direction corresponds to the plate thickness direction of the thin plate and is equivalent to the Z direction. The multiple semiconductor elements 30 included in the first semiconductor element 30H are arranged such that their largest flat surfaces are oriented in a direction perpendicular to both the element arrangement direction and the thickness direction. The multiple semiconductor elements 30 included in the second semiconductor element 30L are arranged such that their largest flat surfaces are oriented in a direction perpendicular to both the element arrangement direction and the thickness direction. As shown in FIG. 2, the multiple semiconductor elements are arranged in the X direction. In contrast, in a configuration where the first semiconductor element and the second semiconductor element are arranged in the X direction, an imbalance occurs because the current in the current path with the shortest distance among the multiple current paths formed between the snubber circuit and the semiconductor elements becomes larger. According to the configuration of this specification, for example, as shown in FIG. 2, multiple current paths formed between the snubber circuit and the semiconductor elements can be arranged in a well-balanced manner.

The semiconductor element 30 is formed by creating a vertical-type device on a semiconductor substrate made of silicon (Si), a wide bandgap semiconductor with a bandgap wider than silicon, or other such materials. Examples of wide bandgap semiconductors include silicon carbide (SiC), gallium nitride (GaN), gallium oxide (GA2O3), and diamond. The semiconductor element 30 may be called a power element, a semiconductor chip, or the like.

The vertical element is configured such that a main current flows in a thickness direction of the semiconductor element 30. The semiconductor element 30 is arranged such that its thickness direction aligns with the Z direction. The semiconductor element 30 has main electrodes on both surfaces in the thickness direction. In this embodiment, the semiconductor element 30 is formed by creating an n-channel MOSFET 11 as a vertical-type device on a semiconductor substrate made of SiC. The semiconductor element 30 has a drain electrode on one surface of the plate as a main electrode, and a source electrode on the other surface of the plate.

When the MOSFET 11 is turned on, a current flows between the main electrodes, that is, between the drain electrode and the source electrode. In the case where the diode 12 is a parasitic diode, the source electrode also serves as the anode electrode, and the drain electrode also serves as the cathode electrode. The drain electrode is the main electrode on the high-potential side, and the source electrode is the main electrode on the low-potential side. The semiconductor element 30 has a rectangular shape in a plan view in the Z direction.

As shown in FIG. 3, the first semiconductor element 30H and the second semiconductor element 30L are arranged at approximately the same height in the Z direction. The multiple semiconductor elements 30 included in the first semiconductor element 30H are arranged in the same orientation so that the drain electrodes are on the P wiring 511 side. The multiple semiconductor elements 30 included in the first semiconductor element 30H are arranged in the same orientation so that the source electrodes are positioned on the side opposite to the P wiring 511. The multiple semiconductor elements 30 included in the second semiconductor element 30L are arranged in the same orientation so that the drain electrodes are on an O wiring 531 side. The multiple semiconductor elements 30 included in the second semiconductor element 30L are arranged in the same orientation as the multiple semiconductor elements 30 of the first semiconductor element 30H, such that the source electrodes are on an N wiring 521 side.

The semiconductor device 21 includes a P terminal 51 that is connected to the drain electrode of the first semiconductor element 30H via the P wiring 511. The semiconductor device 21 includes an N terminal 52 that is connected to the source electrode of the second semiconductor element 30L via the N wiring 521. The P terminal 51 is an external connection terminal that is electrically connected to the P line 7. The P terminal 51 is electrically connected to the positive terminal of the smoothing capacitor 5. The N terminal 52 is an external connection terminal that is electrically connected to the N line 8. The N terminal 52 is electrically connected to the negative terminal of the smoothing capacitor 5.

The P wiring 511 is formed by a single wiring board. The N wiring 521 is formed by a single wiring board. The P terminal 51 is an end portion of the P wiring 511 formed by a single wiring board. The P terminal 51 has a shape that protrudes, in the element arrangement direction, on the side opposite to the semiconductor element group with respect to the snubber circuit component 40. The N terminal 52 is an end portion of the N wiring 521 formed by a single wiring board. The N terminal 52 has a shape that protrudes, in the element arrangement direction, on the side opposite to the semiconductor element group with respect to the snubber circuit component 40. The P wiring board and N wiring board shown in FIG. 3 are provided at positions offset from each other in the thickness direction of the first semiconductor element, which is perpendicular to the element arrangement direction and corresponds to the direction of the minimum dimensional length.

The P wiring 511 is connected to the drain electrode of the first semiconductor element 30H. The P wiring 511 electrically connects the drain electrode of the first semiconductor element 30H and the P terminal 51. The P wiring 511 is connected to the positive electrode part of the snubber circuit 13 included in the snubber circuit component 40. The P wiring 511 electrically connects the positive electrode part of the snubber circuit 13 and the P terminal 51. The P wiring 511 may also be referred to as a positive electrode wiring or a high-potential power supply wiring.

The source electrode of the second semiconductor element 30L is electrically connected to the N wiring 521. The N wiring 521 electrically connects the source electrode of the second semiconductor element 30L to the N terminal 52. The N wiring 521 is connected to the negative electrode part of the snubber circuit 13 included in the snubber circuit component 40. The N wiring 521 may also be referred to as a negative electrode wiring or a low-potential power supply wiring.

The O terminal 53 is an external connection terminal that is electrically connected to the output line 10. The O terminal 53 is electrically connected to the winding 3a of the opposing phase of the motor generator 3. The O terminal 53 may also be referred to as an output terminal or an AC terminal. The O wiring 531 is formed by a single wiring board. The O terminal 53 is an end portion of the O wiring 531, which is formed by a single wiring board. The O terminal 53 has a shape that protrudes, with respect to the element arrangement direction, from the second semiconductor element 30L on the side opposite to the snubber circuit component 40. In the semiconductor device 21, the O terminal 53 protrudes from the side opposite to the P terminal 51 and the N terminal 52. The O wiring 531 is connected to the drain electrode of the second semiconductor element 30L. The O wiring 531 electrically connects the source electrode of the second semiconductor element 30L to the N terminal 52.

An O wiring 532 is formed by a single wiring board. The O wiring 532 is connected to the source electrode of the first semiconductor element 30H. As shown in FIG. 3, the P wiring 511 and the O wiring 531 are arranged at approximately the same height in the Z direction. The P wiring 511 and the O wiring 531 are formed so as to overlap in the element arrangement direction. As shown in FIG. 3, the N wiring 521 and the O wiring 532 are arranged at approximately the same height in the Z direction. The N wiring 521 and the O wiring 532 are formed so as to overlap in the element arrangement direction. The O wiring 532 electrically connects the source electrode of the first semiconductor element 30H and the O wiring 531. The O wiring 531 may also be referred to as an output wiring or the like.

As shown in FIG. 3, the O wiring 531 and the O wiring 532 are electrically connected by a height adjustment member 81. The height adjustment member 81 is a conductive member used to offset and install the height positions of the O wiring 531 and the O wiring 532 in the Z direction.

A signal terminal 54 has a shape that protrudes on the side opposite to the snubber circuit component 40 with respect to the second semiconductor element 30L in the element arrangement direction. In the semiconductor device 21, the signal terminal 54 is located on the same side as the O terminal 53 and protrudes on the side opposite to the P terminal 51 and the N terminal 52. The signal terminal 54 is connected to the pad of the first semiconductor element 30H via a signal wiring.

A signal terminal 55 has a shape that protrudes on the side opposite to the snubber circuit component 40 with respect to the second semiconductor element 30L in the element arrangement direction. In the semiconductor device 21, the signal terminal 55 is located on the same side as the O terminal 53 and protrudes on the side opposite to the P terminal 51 and the N terminal 52. The signal terminal 55 is connected to the pad of the second semiconductor element 30L via a signal wiring.

Each signal terminal electrically connects the semiconductor element 30 to the control circuit board. Each signal terminal is electrically connected to the pad of the semiconductor element 30 via a connecting member such as a bonding wire. The signal terminal only needs to include at least a terminal for applying a drive voltage to the gate electrode of the semiconductor element 30. The signal terminal may also include a terminal for detecting the source potential of the semiconductor element 30. The signal terminal may also include a terminal for detecting the drain potential of the semiconductor element 30. The signal terminal may also include a terminal for detecting the temperature of the semiconductor element 30.

The snubber circuit component 40, as an electronic component, includes at least a capacitor and provides the snubber circuit 13 shown in FIG. 1. The snubber circuit 13 is an RC snubber circuit. The snubber circuit 13 has a resistor 132 in addition to the capacitor 131.

As shown in FIG. 3, the semiconductor device 21 is disposed on one surface of the cooler 70 in the Z direction. The semiconductor device 21 is fixed to the cooler 70. The cooler 70 is in close contact with a heat sink 61, which is a member that promotes heat dissipation. An insulating member 62 is interposed between the heat sink 61 and the N wiring 521 and the O wiring 532. The insulating member 62 is a sheet-like member, grease, gel-like object, or the like, formed from an insulating material. As an example, components other than the cooler 70 and the heat sink 61 shown in FIG. 2 are covered by the housing 60.

The housing 60 is formed using an electrically insulating material such as resin. The housing 60 may be, for example, a resin molded body. The housing 60 may hold some of the components of the semiconductor device 21. Some of the components of the semiconductor device 21 may be integrally molded with the housing 60 as insert parts. The housing 60 may be fixed to the case of the power converter 4 together with the cooler 70. The housing 60 may be formed of, for example, gel or potting resin.

The positional relationship between the snubber circuit component 40 described in this specification and a semiconductor group including the first semiconductor element 30H and the second semiconductor element 30L will be explained with reference to FIGS. 4 to 6. FIGS. 4 to 6 show plan views of the semiconductor device 21 as seen in the thickness direction of the semiconductor element 30.

In FIG. 4, a dashed line indicates an extension line drawn from the outline located at the end portion in the X direction of the outer perimeter of the semiconductor element group, extending toward the snubber circuit component 40 along the element arrangement direction. As shown in FIG. 4, the snubber circuit component 40 is provided, in the X direction, over a range that includes the extension lines of both side edges.

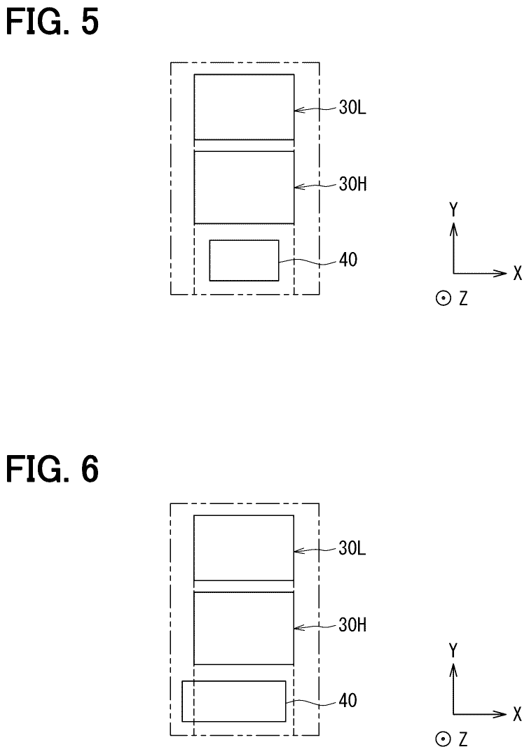

FIG. 5 shows, with a dashed line, the extension lines of the edges located at the end portions in the X direction of the outer perimeter of the semiconductor element group, drawn along the element arrangement direction toward the snubber circuit component 40. As shown in FIG. 4, the snubber circuit component 40 is provided, in the X direction, over a range that is contained within the extension lines of both side edges.

In FIG. 6, a dashed line indicates an extension line drawn from the outline located at the end portion in the X direction of the outer perimeter of the semiconductor element group, extending toward the snubber circuit component 40 along the element arrangement direction. As shown in FIG. 6, the snubber circuit component 40 is provided, in the X direction, over a range that overlaps with one of the extension lines of the side edges.

The operational effects brought about by the semiconductor device 21 disclosed in the specification will be described. The semiconductor device 21 includes the first semiconductor element 30H that is included in the upper arm 9H and the second semiconductor element 30L that is included in the lower arm 9L. The first semiconductor element 30H and the second semiconductor element 30L are aligned to form a semiconductor element group. The semiconductor device 21 includes the snubber circuit component 40 that forms the snubber circuit 13 connected in parallel to the upper arm 9H and the lower arm 9L. The snubber circuit component 40 is provided adjacent to the semiconductor element group in the direction in which the first semiconductor element 30H and the second semiconductor element 30L are aligned.

This semiconductor device 21 includes the snubber circuit component 40 that is adjacent to one of the first semiconductor element 30H and the second semiconductor element 30L, which are aligned, and not adjacent to the other of the first semiconductor element 30H and the second semiconductor element 30L. With this configuration, it is possible to suppress the heat dissipation from the other semiconductor element, which is included in the upper and lower arms, to the snubber circuit 13. Therefore, the semiconductor device 21 can suppress the thermal influence from the semiconductor element group on the snubber circuit 13. Furthermore, the current flowing from the snubber circuit to the drain electrode of the first semiconductor element and the current returning from the source electrode of the second semiconductor element to the snubber circuit flow in opposite directions. Therefore, it is possible to provide a semiconductor device that can reduce the inductance between the semiconductor elements and the snubber circuit.

The semiconductor device 21 includes the P terminal 51 that is connected to the drain electrode of the first semiconductor element via the P wiring 511, and the N terminal 52 that is connected to the source electrode of the second semiconductor element via the N wiring 521. The P terminal 51 and the N terminal 52 are provided so as to protrude on the side opposite to the semiconductor element group with respect to the snubber circuit 13, in the element arrangement direction.

According to this configuration, since the P terminal and N terminal protrude beyond the area where the snubber circuit capacitor is mounted, thermal effects from the semiconductor elements on both terminals can be suppressed. Furthermore, it is possible to form the current from the P terminal to the drain electrode of the first semiconductor element and the current from the source electrode of the second semiconductor element to the N terminal in opposite directions. Therefore, it is possible to provide a semiconductor device that can reduce the inductance between the semiconductor elements and the smoothing capacitor 5. Furthermore, according to this configuration, since the device for cooling the P terminal and N terminal can be made more compact, a power converter equipped with semiconductor devices for three phases can also be made smaller in size.

The P wiring 511 extends from the P terminal 51 so as to form a current to the drain electrode of the first semiconductor element. The N wiring 521 extends so as to form a current from the source electrode of the second semiconductor element to the N terminal 52 in a direction opposite to the current flowing through the P wiring 511. According to this configuration, it is possible to provide a semiconductor device that can reduce the inductance between the semiconductor element and the smoothing capacitor 5.

At least one of the P wiring 511 and the N wiring 521 is formed by a single wiring board. According to this configuration, it is possible to simplify the shapes of the P wiring 511 and the N wiring 521 and to reduce the thickness of the semiconductor device. Therefore, it is possible to provide a semiconductor device that also contributes to the miniaturization of the power converter. This configuration is useful for the miniaturization of the power converter equipped with semiconductor devices for three phases.

Each of the P wiring 511 and the N wiring 521 is formed by a single wiring board. The P wiring board and the N wiring board are provided at positions offset from each other in the thickness direction of the first semiconductor element, which is perpendicular to the element arrangement direction and is also the direction of the minimum dimension length. According to this configuration, it is possible to adopt a structure that allows for compact formation with respect to the length in the thickness direction of the P wiring, N wiring, the first semiconductor element, and the second semiconductor element. Therefore, a highly useful configuration can be provided for achieving miniaturization of the power converter equipped with semiconductor devices for three phases.

The semiconductor device includes the O wiring 532 that connects the source electrode of the first semiconductor element to the drain electrode of the second semiconductor element. The O wiring 532 and the N wiring 521 are formed so as to face each other in the element arrangement direction. According to this configuration, it is possible to adopt a structure that allows for compact formation with respect to the length in the thickness direction of the P wiring, N wiring, O wiring, the first semiconductor element, and the second semiconductor element.

The first semiconductor element 30H and the snubber circuit component 40 are provided so as to overlap in the element arrangement direction. According to this configuration, it is possible to adopt a structure that allows for compact formation with respect to the length in the thickness direction of the first semiconductor element 30H and the snubber circuit component 40.

The power converter 4 includes the semiconductor device described in this specification and the smoothing capacitor 5. Accordingly, as described above, it is possible to provide a power converter that suppresses the thermal influence from the semiconductor element group on the snubber circuit 13.

### Other Embodiments

The disclosure of this specification is not limited to the illustrated embodiments. The disclosure encompasses the illustrated embodiments as well as modifications thereof made by those skilled in the art based on these embodiments. For example, the disclosure is not limited to the combinations of components and elements shown in the embodiments, and may be implemented in various modified forms. The disclosure can be implemented in a variety of combinations. The disclosure may include additional parts that can be added to the embodiments. The disclosure includes embodiments in which parts or elements of the embodiments are omitted. The disclosure encompasses the replacement or combination of components or elements between one embodiment and another embodiment. The technical scope disclosed is not limited to the descriptions of the embodiments. The technical scope disclosed is indicated by the statements in the claims, and should be understood to include all modifications within the meaning and scope equivalent to the statements in the claims.

The power converter 4 according to the aforementioned embodiment may further include a converter as the power conversion circuit. The converter is a DC-DC conversion circuit that converts a DC voltage to a DC voltage of a different value. This converter is provided between the DC power supply 2 and the smoothing capacitor 5. The converter includes, for example, a reactor and the aforementioned upper-lower arm circuits 9. With this configuration, both step-up and step-down operations are possible. The power converter 4 may also include a filter capacitor that removes power supply noise from the DC power supply 2. This filter capacitor is provided between the DC power supply 2 and the converter.

The power converter capable of achieving the objectives disclosed in the specification may have a configuration in which a portion of the snubber circuit overlaps with a portion of the semiconductor elements in the thickness direction.

What is claimed is:

1. A semiconductor device comprising:
a first semiconductor element forming an upper arm;
a second semiconductor element forming a lower arm; and
a snubber circuit component forming a snubber circuit that is connected in parallel to the upper arm and the lower arm, wherein
the first semiconductor element and the second semiconductor element are arranged in an element arrangement direction to form a semiconductor element group,
the snubber circuit component is located adjacent to the semiconductor element group in the element arrangement direction, and
the snubber circuit component is adjacent to one of the first semiconductor element and the second semiconductor element, and is not adjacent to another of the first semiconductor element and the second semiconductor element.

2. The semiconductor device according to claim 1, wherein
each of the first semiconductor element and the second semiconductor element includes a flat-shaped outer shell and a plurality of internal semiconductor elements that are located inside the flat-shaped outer shell,
a thickness direction of each of the plurality of internal semiconductor elements is perpendicular to the element arrangement direction,
a minimum dimension of each of the plurality of internal semiconductor elements is along the thickness direction, and
a largest-area flat surface of each of the plurality of internal semiconductor elements included in each of the first semiconductor element and the second semiconductor element is parallel to a direction perpendicular to both of the element arrangement direction and the thickness direction.

3. The semiconductor device according to claim 1, further comprising:
a P terminal connected to a drain electrode of the first semiconductor element via a P wiring; and
an N terminal connected to a source electrode of the second semiconductor element via an N wiring, wherein
the snubber circuit component is located between the semiconductor element group and each of the P terminal and the N terminal in the element arrangement direction, and
the P terminal and the N terminal protrude in the element arrangement direction, away from the snubber circuit component.

4. The semiconductor device according to claim 3, wherein
the P wiring has an extending path configured to allow a current to flow from the P terminal to the drain electrode of the first semiconductor element, and
the N wiring has an extending path configured to allow a current to flow from the source electrode of the second semiconductor element to the N terminal, in a direction opposite to a direction of current flow through the P wiring.

5. The semiconductor device according to claim 3, wherein
at least one of the P wiring and the N wiring has a single wiring board.

6. The semiconductor device according to claim 5, wherein
each of the P wiring and the N wiring has the single wiring board,
the single wiring board of the P wiring and the single wiring board of the N wiring are at positions offset from each other along a thickness direction of the first semiconductor element, and
a minimum dimension of the first semiconductor element is along the thickness direction that is perpendicular to the element arrangement direction.

7. The semiconductor device according to claim 3, further comprising:
an O wiring that connects the source electrode of the first semiconductor element to the drain electrode of the second semiconductor element,
wherein the O wiring and the N wiring face each other in the element arrangement direction.

8. The semiconductor device according to claim 1, wherein
the first semiconductor element and the snubber circuit component face each other in the element arrangement direction.

9. A power converter comprising:
the semiconductor device according to claim 1; and
a smoothing capacitor.
